(19) United States
(12) Patent Application Publication
(10) Pub. No.: US 2025/0089339 A1
(43) Pub. Date: Mar. 13, 2025

(54) THIN FILM TRANSISTOR AND DISPLAY APPARATUS COMPRISING THE SAME

(71) Applicant: LG Display Co., Ltd., Seoul (KR)

(72) Inventor: JungHyun LEE, Paju-si (KR)

(73) Assignee: LG Display Co., Ltd., Seoul (KR)

(21) Appl. No.: 18/809,641

(22) Filed: Aug. 20, 2024

(30) Foreign Application Priority Data
Sep. 11, 2023 (KR) 10-2023-0120081

(51) Int. Cl. H01L 29/423; H01L 27/12; H01L 29/786

(52) U.S. Cl. CPC H10D 64/519; H10D 30/6755; H10D 86/40; H10D 86/60

(57) ABSTRACT

A thin film transistor includes an active layer; and a gate electrode spaced apart from the active layer and partially overlapping the active layer. The active layer includes a channel area partially overlapping the gate electrode; a source area connected to one side of the channel area; and a drain area connected to the other side of the channel area. The active layer defines an active hole in which the active layer absent, at least a part of the active hole overlaps the gate electrode in a plan view, and at least another part of the active hole extends beyond an edge of the gate electrode. The gate electrode includes a body portion and a protrusion portion protruding in a first direction, the first direction being a direction parallel to the shortest line connecting the source area and the drain area.

### CROSS-REFERENCE TO RELATED APPLICATIONS

This application claims the benefit of priority of the Korean Patent Application No. 10-2023-0120081 filed on Sep. 11, 2023, which is hereby incorporated by reference as if fully set forth herein.

### BACKGROUND

### Technical Field

The present disclosure relates to a thin film transistor and a display apparatus including the same.

### Discussion of the Related Art

Transistors are widely used as switching devices or driving devices in the field of electronic devices. In particular, because a thin film transistor may be manufactured on a glass substrate or a plastic substrate, a thin film transistor is widely used as a switching device of a display apparatus, such as a liquid crystal display apparatus or an organic light emitting device.

Based on the material constituting the active layer, thin film transistors can be divided into amorphous silicon thin film transistors using amorphous silicon as the active layer, polycrystalline silicon thin film transistors using polycrystalline silicon as the active layer, and oxide semiconductor thin film transistors using oxide semiconductors as the active layer.

The amorphous silicon thin film transistor (a-Si TFT) has the advantage of short manufacturing process time and low production cost because amorphous silicon can be deposited in a short time to form an active layer. But, the amorphous silicon thin film transistor has the disadvantage of being limited in use in active matrix organic light emitting devices (AMOLEDs) because of low mobility and poor current driving ability and a change in threshold voltage.

Polycrystalline silicon thin film transistor (poly-Si TFT) is made by crystallizing amorphous silicon after amorphous silicon is deposited. Because a process of crystallizing amorphous silicon is required in the manufacturing process of a polycrystalline silicon thin film transistor, the manufacturing cost increases as the number of processes increases, and because the crystallization process is performed at a high process temperature, it is difficult to apply the polycrystalline silicon thin film transistor to a large area device. In addition, due to its polycrystalline properties, it is difficult to secure the uniformity of the polycrystalline silicon thin film transistor.

In an oxide semiconductor thin film transistor (TFT), because the oxide constituting the active layer can be formed at a relatively low temperature, has high mobility, and has a large resistance change according to the oxygen content, desired physical properties can be easily obtained. Also, due to the nature of the oxide, because the oxide semiconductor is transparent, it is also advantageous to implement a transparent display.

In the oxide semiconductor, when the width of the active layer increases, the penetration depth of the conductorization increases and the length of the effective channel decreases, so that the driving stability of the thin film device may be deteriorated. Therefore, technologies for controlling the penetration depth of the conductorization are continuously being studied.

### SUMMARY

Accordingly, embodiments of the present disclosure are directed to a thin film transistor and a display apparatus including the same that substantially obviates one or more of the problems due to limitations and disadvantages of the related art.

An aspect of the present disclosure is to provide a thin film transistor that prevents or suppresses the threshold voltage Vth from shifting in the negative (−) direction even if the channel area has a short channel, including a protrusion portion portioin and an active hole.

Another aspect of the present disclosure is to provide a thin film transistor in which a conductorization penetration depth is controlled even if the thin film transistor has a short channel by including a protrusion portion and an active hole.

Another aspect of the present disclosure is to provide a thin film transistor with improved reliability, including a protrusion portion and an active hole.

Another aspect of the present disclosure is to provide a display apparatus including such a thin film transistor.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a thin film transistor comprises an active layer; and a gate electrode spaced apart from the active layer and partially overlapping the active layer, wherein the active layer includes: a channel area partially overlapping the gate electrode in a plan view; a source area connected to one side of the channel area in the plan view; and a drain area connected to the other side of the channel area in the plan view, wherein the active layer defines an active hole in which the active layer absent, at least a part of the active hole overlaps the gate electrode in the plan view, and at least another part of the active hole extends beyond an edge of the gate electrode in the plan view, and wherein the gate electrode includes a body portion and a protrusion portion protruding in a first direction, the first direction being a direction parallel to the shortest line connecting the source area and the drain area.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles.

FIG. 1 is a plan view of a thin film transistor according to an embodiment of the present disclosure.

FIG. 2 is a cross-sectional view taken along line I-I′ of FIG. 1.

FIG. 3 is a cross-sectional view taken along line II-II′ of FIG. 1.

FIG. 4 is a plan view of a thin film transistor according to another embodiment of the present disclosure.

FIG. 5 is a plan view of a thin film transistor according to another embodiment of the present disclosure.

FIG. 6 is a plan view of a thin film transistor according to another embodiment of the present disclosure.

FIG. 7 is a plan view of a thin film transistor according to another embodiment of the present disclosure.

FIG. 8 is a plan view of a thin film transistor according to another embodiment of the present disclosure.

FIG. 9 is a plan view of a thin film transistor according to another embodiment of the present disclosure.

FIG. 10 is a plan view of a thin film transistor according to another embodiment of the present disclosure.

FIG. 11 is a plan view of a thin film transistor according to another embodiment of the present disclosure.

FIG. 12 is a plan view of a thin film transistor according to another embodiment of the present disclosure.

FIG. 13A is a plan view of a thin film transistor according to another embodiment of the present disclosure.

FIG. 13B is a plan view of a thin film transistor according to another embodiment of the present disclosure.

FIG. 14A is a plan view of a thin film transistor according to a comparative example.

FIG. 14B is a plan view of a thin film transistor according to another embodiment of the present disclosure.

FIG. 15 is a graph of a threshold voltage Vth measurement of a thin film transistor according to embodiments and comparative examples.

FIG. 16 is a plan view of a thin film transistor according to another embodiment of the present disclosure.

FIG. 17 is a schematic diagram of a display apparatus according to an embodiment of the present disclosure.

FIG. 18 is a schematic diagram of a shift register.

FIG. 19 is a circuit diagram of any one pixel of FIG. 17.

FIG. 20 is a plan view of the pixel of FIG. 19.

FIG. 21 is a cross-sectional view taken along line III-III′ of FIG. 20.

FIG. 22 is a circuit diagram of any one pixel of a display apparatus according to another embodiment of the present disclosure.

FIG. 23 is a circuit diagram of any one pixel of a display apparatus according to another embodiment of the present disclosure.

FIG. 24 is a circuit diagram of any one pixel of a display apparatus according to another embodiment of the present disclosure.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where “comprise,” “have,” and “include” described in the present disclosure are used, another portion may be added unless “only˜” is used. The terms of a singular form may include plural forms unless referred to the contrary.

In construing an element, the element is construed as including an error band although there is no explicit description.

In describing a position relationship, for example, when the position relationship is described as “upon˜,” “above˜,” “below˜,” and “next to˜,” one or more portions may be disposed between two other portions unless “just” or “direct” is used.

Spatially relative terms, such as “below,” “beneath,” “lower,” “above,” and “upper,” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below” or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing embodiments of the present disclosure, the same components can have the same sign as can be displayed on the other drawings.

In the embodiments of the present disclosure, a source electrode and a drain electrode are distinguished for convenience of description, and the source electrode and the drain electrode may be interchanged. The source electrode may be the drain electrode and vice versa. In addition, the source electrode of any one embodiment may be a drain electrode in another embodiment, and the drain electrode of any one embodiment may be a source electrode in another embodiment.

In some embodiments of the present disclosure, for convenience of description, a source area is distinguished from a source electrode, and a drain area is distinguished from a drain electrode, but embodiments of the present disclosure are not limited thereto. The source area may be the source electrode, and the drain area may be the drain electrode. In addition, the source area may be the drain electrode, and the drain area may be the source electrode.

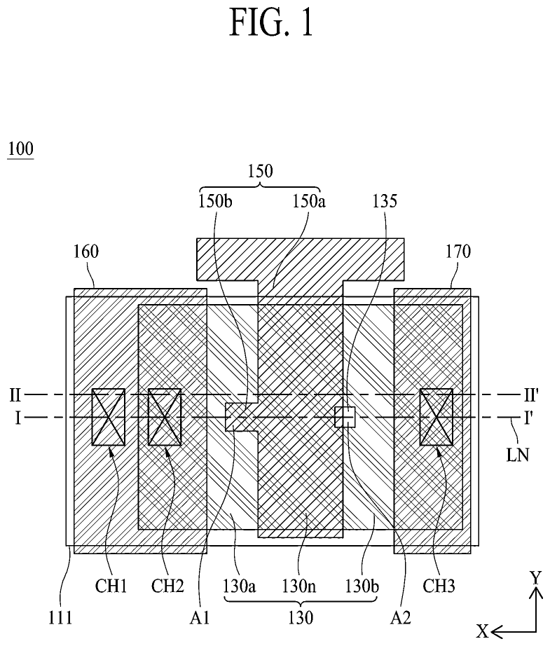

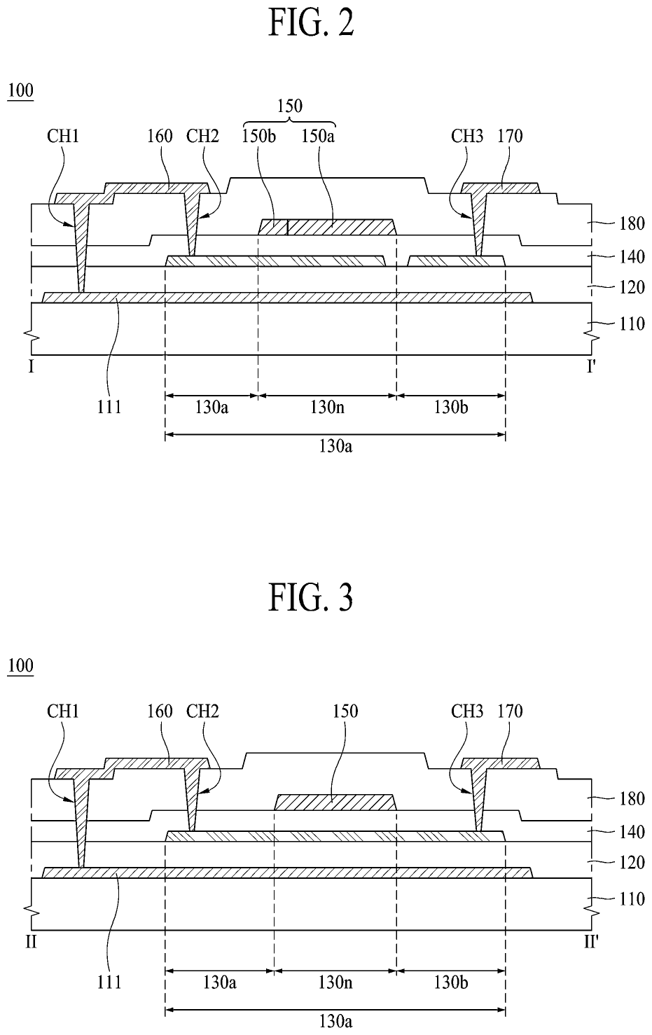

FIG. 1 is a plan view of a thin film transistor 100 according to an embodiment of the present disclosure. FIG. 2 is a cross-sectional view taken along line I-I′ of FIG. 1. FIG. 3 is a cross-sectional view taken along line II-II′ of FIG. 1.

With reference to FIGS. 1, 2, and 3, an active layer 130 on the base substrate 110 and a gate electrode 150 spaced apart from the active layer 130 and partially overlapping the active layer 130 may be included. According to an embodiment of the present disclosure, the thin film transistor 100 may further include the base substrate 110. As shown in FIGS. 2 and 3, the active layer 130 is disposed on the base substrate 110.

According to an embodiment of the present disclosure, the thin film transistor 100 may further include a buffer layer 120. With reference to FIGS. 2 and 3, the active layer 130 is disposed on the buffer layer 120. For example, the buffer layer 120 may be disposed between the base substrate 110 and the active layer 130.

According to an embodiment of the present disclosure, the thin film transistor 100 may further include a gate insulating layer 140. With reference to FIGS. 2 and 3, the gate insulating layer 140 is disposed on the active layer 130. For example, the gate insulating layer 140 may be disposed between the active layer 130 and the gate electrode 150.

According to an embodiment of the present disclosure, the thin film transistor 100 may further include another layer disposed on the gate electrode 150. For example, the thin film transistor 100 may further include an interlayer insulating layer 180. In FIG. 3, the interlayer insulating layer 180 is disposed on the gate electrode 150. For example, the gate electrode 150 is disposed between the gate insulating layer 140 and the interlayer insulating layer 180.

According to an embodiment of the present disclosure, the thin film transistor 100 may further include a source electrode 160 and a drain electrode 170. With reference to FIGS. 1, 2, and 3, the source electrode 160 and the drain electrode 170 are disposed on the gate insulation layer 140.

Hereinafter, components of the thin film transistor 100 according to an embodiment of the present disclosure will be described in more detail.

Glass or plastic may be used as the base substrate 110. A transparent plastic having flexible characteristics, such as plastic, for example, polyimide, may be used. When polyimide is used as the base substrate 110, considering that a high-temperature deposition process is performed on the base substrate 110, heat-resistant polyimide capable of withstanding high-temperature may be used. In this case, in order to form a thin film transistor, processes, such as deposition, etching, and the like, may be performed in a state in which a polyimide substrate is disposed on a carrier substrate made of a highly durable material, such as glass.

As shown in FIGS. 2 and 3, a buffer layer 120 may be disposed on the base substrate 110. The buffer layer 120 may be formed on the base substrate 110 and may be formed of an inorganic material or an organic material. For example, insulating oxides, such as silicon oxide (SiOx), aluminum oxide (Al2O3) and the like, may be included.

The buffer layer 120 blocks impurities, such as moisture and oxygen flowing from the base substrate 110, to protect the active layer 130, and planarize the upper portion of the base substrate 110. The buffer layer 120 may be formed as a single layer or a plurality of layers.

As shown in FIGS. 2 and 3, the active layer 130 may be disposed on the buffer layer 120. The active layer 130 may include a channel area 130n, a source area 130a, and a drain area 130b. The channel area 130n overlaps the gate electrode 150. The channel area 130n serves as a channel of the thin film transistor 100. For example, the active layer 130 may include a channel area 130n partially overlapping the gate electrode 150 in a plane, a source area 130a connected to one side of the channel area 130n without overlapping the gate electrode 150 in a plane, and a drain area 130b connected to the other side of the channel area 130n without overlapping the gate electrode 150 in a plane.

According to an embodiment of the present disclosure, the source area 130a and the drain area 130b are spaced apart from each other with the channel area 130n interposed therebetween.

According to a configuration of the present disclosure, the active layer 130 may be formed of a semiconductor material. The active layer 130 may include an oxide semiconductor material.

The oxide semiconductor material may include at least one of an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, an ITZO (InSnZnO)-based oxide semiconductor material, and a FIZO (FeInZnO)-based oxide semiconductor material. However, embodiments of the present disclosure are not limited thereto, and the active layer 130 may be made of another oxide semiconductor material known in the art.

The source area 130a and the drain area 130b may be formed by selectively conductorization with respect to the active layer 130 made of a semiconductor material. According to an embodiment of the present disclosure, imparting conductivity to a specific portion of the active layer 130 so that the same may function as a conductor is called selective conductorization. A portion to which conductivity is imparted by selective conductorization is converted into a conductor, and a portion to which conductivity is not imparted is not converted into a conductor. The source area 130a and the drain area 130b shown in FIGS. 1, 2 and 3 are portions to which conductivity is imparted by selective conductorization.

According to an embodiment of the present disclosure, a selective conductorization may be formed by doping using a dopant. In addition, a selective conductorizationi may be formed by plasma treatment.

Selective conductorization of the active layer 130 may be performed by dopant doping using the gate electrode 150 or a photoresist as a mask. The dopant may include at least one of boron (B), phosphorus (P), fluorine (F), and hydrogen (H), for example.

When the active layer 130 is selectively conductorized by doping the dopant, the region of the active layer 130 doped with the dopant is selectively conductorized to become a source area 130a or a drain area 130b. The region of the active layer 130 that is not doped with the dopant may not be conductorized, and may become a channel area 130n.

Alternatively, the active layer 130 may be selectively conductorized by plasma treatment applied to a process of patterning the gate insulating layer 140. For example, plasma may be used in a process of patterning the gate insulating layer 140, and a portion of the active layer 130 contacting the plasma may be selectively conductorized to become a source area 130a or a drain area 130b of the active layer 130. A portion of the active layer 130 that is protected by the gate insulating layer 140 and is not in contact with the plasma may be a channel area 130n without being conductorized.

A configuration in which the active layer 130 is formed of one layer is disclosed in FIGS. 1, 2 and 3, but configurations of the present disclosure are not limited thereto. The active layer 130 may have a single layer structure or a multilayer structure.

With reference to FIGS. 1, 2 and 3, an active hole 135 in which the active layer 130 is not disposed is disposed in an area in which an edge is defined by the active layer 130. According to an embodiment of the present disclosure, the active hole 135 is disposed in an area defined by the active layer 130 on a plane. For example, the active hole 135 may be an area formed by removing a portion of the active layer 130.

As shown in FIGS. 1 and 2, the active hole 135 may be a region formed by removing a portion of the active layer 130. Because the active hole 135 may be referred to as a hole formed in the active layer 130 by removing a portion of the active layer 130, according to an embodiment of the present disclosure, the hole is referred to as an “active hole”.

According to an embodiment of the present disclosure, at least a portion of the active hole 135 may overlap the gate electrode 150. FIGS. 1, 2, and 3 show a configuration in which a portion of the active hole 135 overlaps the gate electrode 150. However, an embodiment of the present disclosure is not limited thereto, and the entire active hole 135 may overlap the gate electrode 150.

The gate insulating layer 140 is disposed on the active layer 130. The gate insulating layer 140 protects the channel area 130n.

The gate insulating layer 140 has insulating properties. The gate insulating layer 140 may include at least one of, for example, silicon oxide, silicon nitride, and metallic oxide. The gate insulating layer 140 may have a single layer structure or a multilayer structure.

In FIGS. 2 and 3, the gate insulating layer 140 is not patterned and may be disposed on the entire surface of the base substrate 110. However, embodiments of the present disclosure are not limited thereto, and the gate insulating layer 140 may have a patterned structure.

The gate electrode 150 is disposed on the gate insulating film 140. The gate electrode 150 overlaps the channel area 130n of the active layer 130.

The gate electrode 150 may include at least one among an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, and chromium (Cr), tantalum (Ta), neodium (Nd), and titanium (Ti). The gate electrode 150 may have a multilayer structure including at least two conductive layers each having different physical properties. For example, the gate electrode 150 may include at least one of molybdenum (Mo) and titanium (Ti).

According to an embodiment of the present disclosure, the gate insulating layer 140 may be patterned by etching using the gate electrode 150 as a mask, and in this process, the active layer 130 may be selectively conductorized to form a source area 130a and a drain area 130b. For example, according to an embodiment of the present disclosure, a region of the active layer 130 overlapping the gate electrode 150 is not conductorized to form a channel area 130n having semiconductor characteristics, and a region not overlapping the gate electrode 150 may be conductive to form a source area 130a and a drain area 130b.

In FIG. 1, when a direction parallel to a shortest line connecting the source area 130a and the drain area 130b is referred to as a first direction X and a direction perpendicular to the first direction X is referred to as a second direction Y, the gate electrode 150 may include a body portion 150a and a protrusion portion 150b protruding in the first direction X. For example, the protrusion portion 150b may protrude from the body portion 150a in the first direction X. Further, the protrusion portion 150b may protrude from the body portion 150a and overlaps the active layer 130.

As illustrated in FIG. 1, the length of an area in which a straight line passing through the protrusion portion 150b overlaps the source area 130a and the drain area 130b among any straight lines parallel to the first direction X in a plan view may be shorter than a length of an area in which a straight line that does not pass through the protrusion portion 150b overlaps the source area 130a and the drain area 130b among any straight lines parallel to the first direction in a plan view.

For example, in FIG. 1, when the lengths of the source area 130a and the drain area 130b based on the first direction X are “the width of the source area” and “the width of the drain area”, respectively, the width of the source area 130a disposed on the same line as the protrusion portion 150b based on the first direction X may be smaller than the width of the source area 130a not disposed on the same line as the protrusion portion 150b.

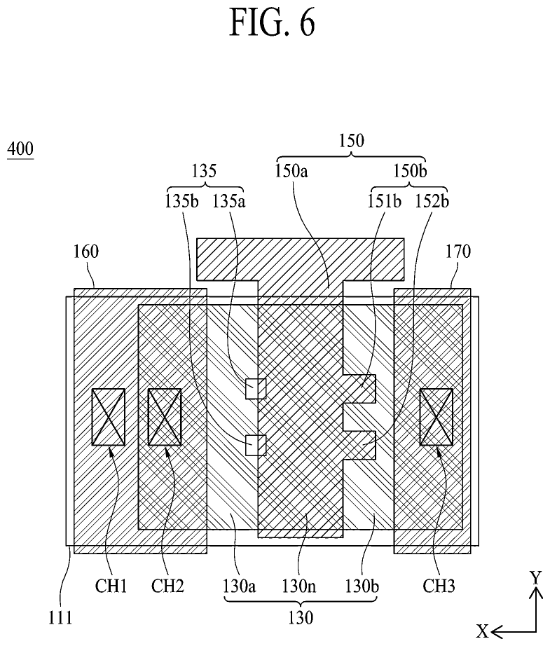

In FIG. 1, a configuration in which the protrusion portion 150b is disposed toward the source area 130a in the first direction X is illustrated. However, embodiments of the present disclosure are not limited thereto, and the protrusion portion 150b may be disposed toward the drain area 130b in the first direction X (see FIG. 6).

As shown in FIGS. 2 and 3, an interlayer insulating layer 180 may be disposed on the gate electrode 150. The interlayer insulating layer 180 may be formed of an organic or inorganic insulating material. The interlayer insulating layer 180 may be formed of a composite layer of an organic layer and an inorganic layer.

According to an embodiment of the present disclosure, the thin film transistor 100 may include a source electrode 160 and a drain electrode 170 disposed on the interlayer insulating layer 180. Positions of the source electrode 160 and the drain electrode 170 may be reversed. However, embodiments of the present disclosure are not limited thereto, and the source area 130a and the drain area 130b may serve as source and drain electrodes, respectively.

With reference to FIGS. 1, 2, and 3, the source electrode 160 and the drain electrode 170 may be connected to the active layer 130 through a contact hole CH2 and a contact hole CH3, respectively. For example, the source electrode 160 may be in contact with the source area 130a through a contact hole. The drain electrode 170 may be spaced apart from the source electrode 160 and may be in contact with the drain area 130b through a contact hole.

With reference to FIGS. 1, 2, and 3, the light blocking layer 111 may be disposed on the base substrate 110. For example, the light blocking layer 111 may be disposed between the base substrate 110 and the active layer 130. The light blocking layer 111 overlaps the channel area 130n. The light blocking layer 111 blocks light incident from the outside, thereby protecting the channel area 130n.

The light blocking layer 111 may be formed of a material having light blocking characteristics. The light blocking layer 111 may include at least one of an aluminum-based metal, such as aluminum (Al) or an aluminum alloy, a molybdenum-based metal, such as molybdenum (Mo) or a molybdenum alloy, chromium (Cr), tantalum (Ta), neodium (Nd), titanium (Ti), and iron (Fe). According to an embodiment of the present disclosure, the light blocking layer 111 may have electrical conductivity.

The light blocking layer 111 may be omitted. Although not illustrated in FIGS. 1, 2 and 3, a buffer layer may be additionally disposed between the base substrate 110 and the light blocking layer 111. The light blocking layer 111 may be electrically connected to one of the source electrode 160 and the drain electrode 170. FIG. 2 illustrates a configuration in which the light blocking layer 111 is electrically connected to the source electrode 160 through a contact hole CH1.

According to an embodiment of the present disclosure, a portion of the active hole 135 may not overlap the gate electrode 150. FIG. 1 illustrates a configuration in which a portion of the active hole 135 overlaps a portion of the gate electrode 150, and another portion of the active hole 135 is disposed from the gate electrode 150 toward the drain area 130b along the first direction X in a plan view.

According to an embodiment of the present disclosure, if a direction parallel to the shortest line connecting the source area 130a and the drain area 130b is defined as the first direction X, the length of the channel area 130n in the first direction X may be defined as the length of the channel area, and if a direction perpendicular to the first direction X is defined as the second direction Y, the width of the channel area 130n in the second direction Y may be defined as the width of the channel area.

When the channel area 130n has a large width, when conductorization with respect to the source area 130a and the drain area 130b is performed, an interface between the channel area 130n and the conductorizatioin portion is increased, and thus conductorization diffusion toward the channel area 130n may be greatly performed. When conductorization diffusion toward the channel area 130n is greatly performed, the threshold voltage Vth of the thin film transistor 100 may move in a negative (−) direction, and driving stability of the thin film transistor 100 may be deteriorated.

On the other hand, when the channel area 130n has a small width, when conductorization with respect to the source area 130a and the drain area 130b is performed, the interface between the channel area 130n and the conductorizatioin portion may be reduced, and thus the conductorization diffusion toward the channel area 130n may be suppressed.

According to an embodiment of the present disclosure, as illustrated in FIG. 1, the active hole 135 is formed in the boundary region between the channel area 130n and the drain area 130b. As a result, the boundary surface between the channel area 130n and the drain area 130b is reduced, and thus, conductorization diffusion toward the channel area 130n may be suppressed.

As a result, it is possible to prevent or suppress the threshold voltage Vth of the thin film transistor 100 from being shifted in the negative (−) direction.

In FIG. 1, a straight line LN passing through at least a portion of the active hole 135 among straight lines parallel to the first direction X may pass through the protrusion portion 150b. For example, at least a portion of the protrusion portion 150b and at least a portion of the active hole 135 may be disposed on an arbitrary straight line extending along the first direction in a plane.

The active hole 135 is an area in which the active layer 130 is not disposed within an area in which an edge thereof is defined by the active layer 130. Accordingly, a length of the channel area 130n may be narrowed in the channel area 130n as compared with an area in which the active hole 135 is not disposed based on the first direction X.

On the other hand, when the straight line LN passing through at least a portion of the active hole 135 among the straight lines parallel to the first direction X passes through the protrusion portion 150b, for example, when the active hole 135 and the protrusion portion 150b are arranged on a straight line based on the first direction X, the length of the channel area 130n may be secured by the protrusion portion 150b, and conductorization penetration may be very small.

As a result, the thin film transistor may be driven even by a short channel having the length of the short channel area 130n, a short channel may be implemented, the design accuracy of the channel area 130n may be improved, and the design of the channel area 130n may be facilitated.

In addition, when the straight line (LN) passing through at least a portion of the active hole (135) passes through the protrusion portion (150b) among the straight lines parallel to the first direction (X), for example, when the active hole (135) and the protrusion portion (150b) are arranged on a straight line based on the first direction (X), the threshold voltage (Vth) may be prevented from shifting in the negative (−) direction even by a short channel having the length of the short channel area (130n).

According to an embodiment of the present disclosure, the area of the region A1 occupied by the protrusion portion 150b on a plane may be larger than the area of the region A2 occupied by the active hole 135. Accordingly, the length of the channel area 130n may be secured, and conductorization penetration may hardly occur or may be very small. As a result, the thin film transistor may be driven even by the short channel having the length of the short channel area 130n, and a short channel may be implemented.

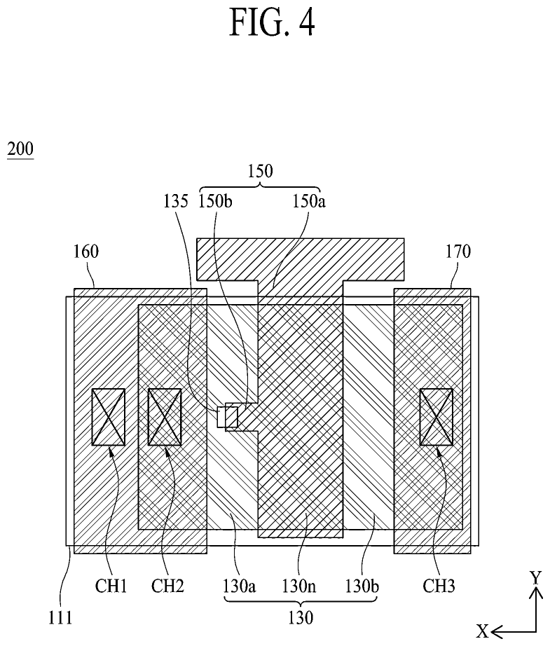

FIG. 4 is a plan view of a thin film transistor 200 according to another embodiment of the present disclosure.

According to an embodiment of the present disclosure, the protrusion portion 150b may overlap at least a portion of the active hole 135. However, embodiments of the present disclosure are not limited thereto, and the protrusion portion 150b may not overlap the active hole 135 (see FIG. 1). FIG. 4 illustrates a configuration in which the protrusion portion 150b overlaps a portion of the active hole 135.

In FIG. 4, even when the protrusion portion 150b overlaps at least a portion of the active hole 135, the length of the channel area 130n may be secured by the protrusion portion 150b, and conductorization penetration may hardly occur or may be very small. As a result, a thin film transistor may be driven even by a short channel having the length of the short channel area 130n, and a short channel may be implemented.

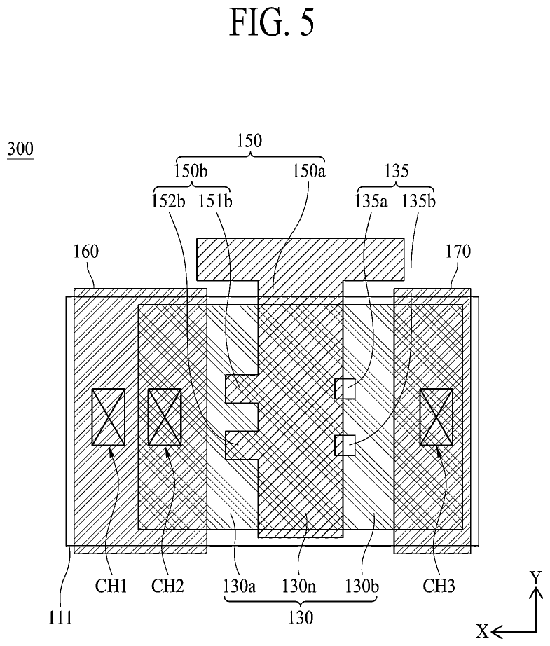

FIG. 5 is a plan view of a thin film transistor 300 according to another embodiment of the present disclosure.

With reference to FIG. 5, the protrusion portion 150b may include a first protrusion portion 151b and a second protrusion portion 152b spaced apart from each other, and the active hole 135 may include a first active hole 135a and a second active hole 135b spaced apart from each other. In this case, each of the first protrusion portion 151b and the second protrusion portion 152b may be disposed toward the source area 130a in a plane, or may be disposed toward the drain area 130b.

Although FIG. 5 shows a configuration in which the protrusion portions 150b includes a first protrusion portion 151b and a second protrusion portion 152b spaced apart from each other, embodiments of the present disclosure are not limited thereto, and a third protrusion portion and a fourth protrusion portion may be further included or five or more. In this case, the respective protrusion portions 150b are spaced apart from each other.

Also, although FIG. 5 shows a configuration in which the active holes 135 includes a first active hole 135a and a second active hole 135b spaced apart from each other, embodiments of the present disclosure are not limited thereto, and may further include, or may be five or more third active holes 135c and fourth active holes 135d. In this case, the respective active holes 135 are spaced apart from each other.

In FIG. 5, the first protrusion portion 151b and the second protrusion portion 152b are disposed toward the source area 130a in a plane, the first active hole 135a and the second active hole 135b are disposed from the gate electrode 150 toward the drain area 130b in the first direction X in a plane, the first active hole 135a and the second active hole 135b do not overlap the protrusion portion 150b, and a straight line passing at least a portion of the active hole 135 among straight lines parallel to the first direction X passes through the protrusion portion 150b.

For example, a straight line passing through at least a portion of the first active hole 135a among straight lines parallel to the first direction X may pass through the first protrusion portion 151b, and a straight line passing through at least a portion of the second active hole 135b among straight lines parallel to the first direction X may pass through the second protrusion portion 152b.

In the case of the thin film transistor 300 according to FIG. 5, the length of the channel area 130n may be secured by the protrusion portion 150b and the active hole 135, and conductorizatioin penetration may hardly occur or may be very small. As a result, the thin film transistor 300 may be driven even by the short channel having the length of the short channel area 130n, and a short channel may be implemented.

FIG. 6 is a plan view of a thin film transistor 400 according to another embodiment of the present disclosure.

In FIG. 6, the first protrusion portion 151b and the second protrusion portion 152b are disposed toward the drain area 130b in a plane, the first active hole 135a and the second active hole 135b are disposed from the gate electrode 150 toward the source area 130a in the first direction X in a plane, the first active hole 135a and the second active hole 135b do not overlap the protrusion portion 150b, and a straight line passing at least a portion of the active hole 135 among straight lines parallel to the first direction X passes through the protrusion portion 150b.

For example, a straight line passing through at least a portion of the first active hole 135a among straight lines parallel to the first direction X may pass through the first protrusion portion 151b, and a straight line passing through at least a portion of the second active hole 135b among straight lines parallel to the first direction X may pass through the second protrusion portion 152b.

In the case of the thin film transistor 400 according to FIG. 6, the length of the channel area 130n may be secured by the protrusion portion 150b and the active hole 135, and conductorization penetration may hardly occur or may be very small. As a result, the thin film transistor 400 may be driven even by the short channel having the length of the short channel area 130n, and a short channel may be implemented.

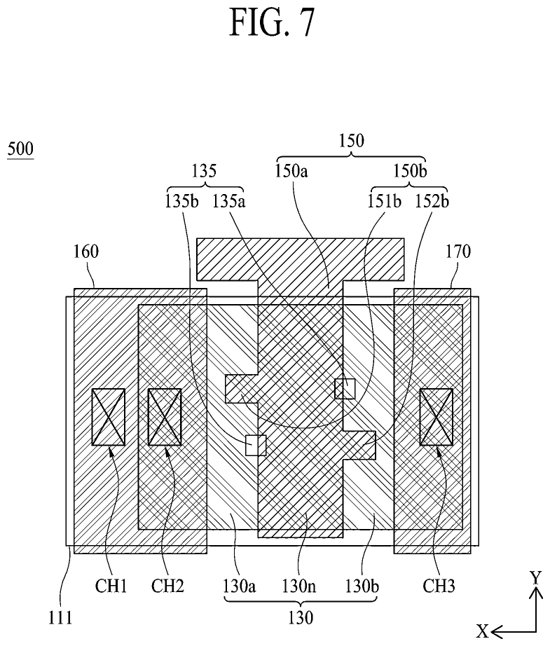

FIG. 7 is a plan view of a thin film transistor 500 according to another embodiment of the present disclosure.

In FIG. 7, any one of the first protrusion portion 151b and the second protrusion portion 152b is disposed toward the source area 130a in a plane, the other is disposed toward the drain area 130b, any one of the first active hole 135a and the second active hole 135b is disposed toward the source area 130a from the gate electrode 150 along the first direction X in a plane, the other is disposed toward the drain area 130b, the first active hole 135a and the second active hole 135b do not overlap the protrusion portion 150b, and a straight line passing at least a portion of the active hole 135 among straight lines parallel to the first direction X passes through the protrusion portion 150b.

Further, in FIG. 7, a straight line passing through at least a portion of the first protrusion portion 151b among straight lines parallel to the first direction X does not pass through the second protrusion portion 152b. Also, in FIG. 7, a straight line passing through at least a portion of the first active hole 135a among straight lines parallel to the first direction X does not pass through the second active hole 135b.

In the case of the thin film transistor 500 according to FIG. 7, the length of the channel area 130n may be secured by the protrusion portion 150b and the active hole 135, and conductorization penetration may hardly occur or may be very small. As a result, the thin film transistor 500 may be driven even by the short channel having the length of the short channel area 130n, and a short channel may be implemented.

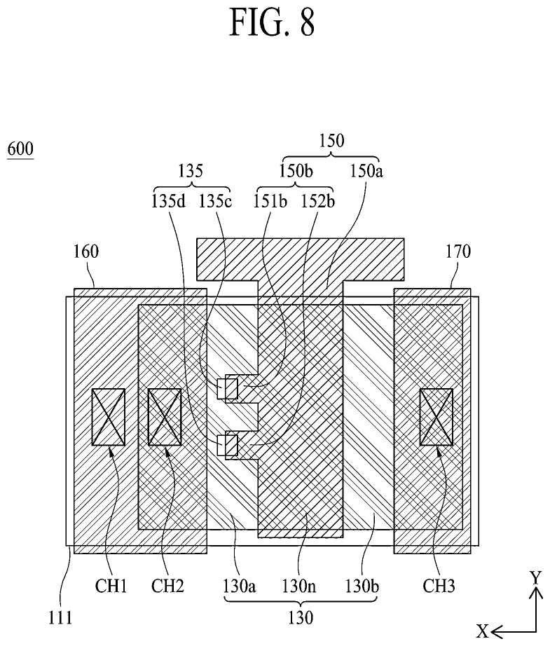

FIG. 8 is a plan view of a thin film transistor 600 according to another embodiment of the present disclosure.

According to an embodiment of the present disclosure, the active hole 135 may include a third active hole 135c and a fourth active hole 135d spaced apart from each other. Each of the third active hole 135c and the fourth active hole 135d may overlap the protrusion portion 150b.

In FIG. 8, the first protrusion portion 151b and the second protrusion portion 152b are disposed to be spaced apart from each other, the third active hole 135c and the fourth active hole 135d are disposed to be spaced apart from each other, the third active hole 135c overlaps the first protrusion portion 151b, and the fourth active hole 135d overlaps the second protrusion portion 152b. However, embodiments of the present disclosure are not limited thereto, and the third active hole 135c may overlap the second protrusion portion 152b, and the fourth active hole 135d may overlap the first protrusion portion 151b.

In the case of the thin film transistor 600 according to FIG. 8, the length of the channel area 130n may be secured by the protrusion portion 150b and the active hole 135, and conductorization penetration may hardly occur or may be very small. As a result, the thin film transistor 600 may be driven even by the short channel having the length of the short channel area 130n, and a short channel may be implemented.

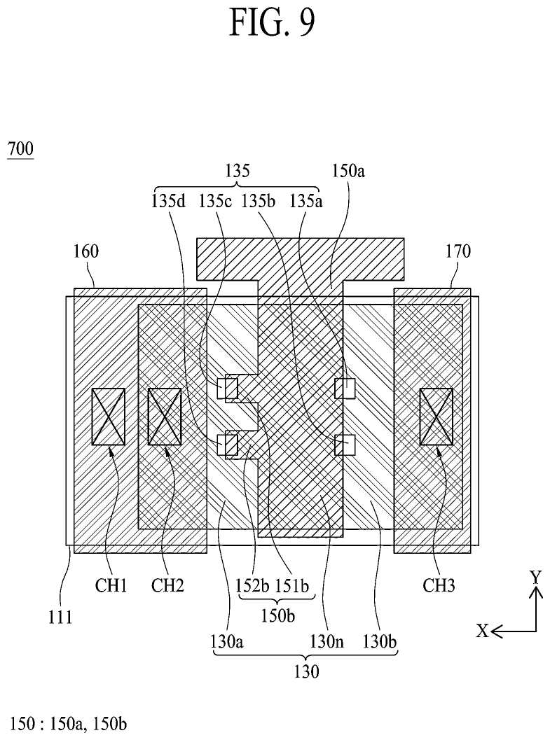

FIG. 9 is a plan view of a thin film transistor 700 according to another embodiment of the present disclosure.

As compared with FIG. 8, FIG. 9 may further include a first active hole 135a and a second active hole 135b spaced apart from each other. As shown in FIG. 9, the first protrusion portion 151b and the second protrusion portion 152b are disposed to be spaced apart from each other, the third active hole 135c and the fourth active hole 135d are disposed to be spaced apart from each other, the third active hole 135c overlaps the first protrusion portion 151b, the fourth active hole 135d overlaps the second protrusion portion 152b, the first active hole 135a and the second active hole 135b do not overlap the protrusion portion 150b, at least a portion of the first protrusion portion 151b, at least a portion of the first active hole 135a, and at least a portion of the third active hole 135c are disposed in a straight line extending along the first direction X in a plane, at least a portion of the second protrusion portion 152b, at least a portion of the second active hole 135b, and at least a portion of the fourth active hole 135d are disposed in a straight line extending along the first direction X in a plane.

Further, FIG. 9 shows a configuration in which the first protrusion portion 151b and the second protrusion portion 152b are disposed toward the source area 130a, and the first active hole 135a and the second active hole 135b are disposed from the gate electrode 150 toward the drain area 130b along the first direction X in a plan view.

However, embodiments of the present disclosure are not limited thereto, and positions of the first protrusion portion 151b and the second protrusion portion 152b may be changed, positions of the first active hole 135a and the second active hole 135b may be changed, and positions of the third active hole 135c and the fourth active hole 135d may be changed.

In the case of the thin film transistor 700 according to FIG. 9, the length of the channel area 130n may be secured by the protrusion portion 150b and the active hole 135, and conductorization penetration may hardly occur or may be very small. As a result, the thin film transistor 700 may be driven even by the short channel having the length of the short channel area 130n, and a short channel may be implemented.

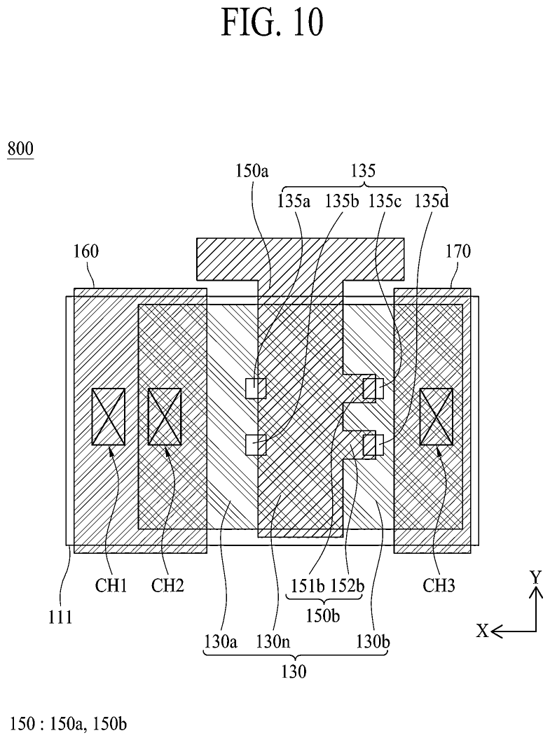

FIG. 10 is a plan view of a thin film transistor 800 according to another embodiment of the present disclosure.

Compared with FIG. 9, FIG. 10 illustrates a configuration in which the first protrusion portion 151b and the second protrusion portion 152b are disposed toward the drain area 130b, and the first active hole 135a and the second active hole 135b are disposed from the gate electrode 150 toward the source area 130a along the first direction X in a plan view.

In the case of the thin film transistor 800 according to FIG. 10, the length of the channel area 130n may be secured by the protrusion portion 150b and the active hole 135, and conductorization penetration may hardly occur or may be very small. As a result, the thin film transistor 800 may be driven even by the short channel having the length of the short channel area 130n, and a short channel may be implemented.

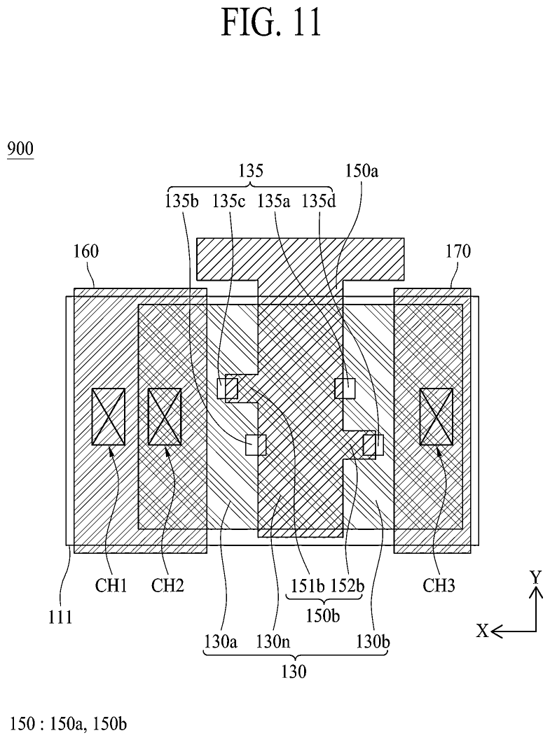

FIG. 11 is a plan view of a thin film transistor 900 according to another embodiment of the present disclosure.

Compared with FIG. 10, in FIG. 11, one of the first protrusion portion 151b and the second protrusion portion 152b is disposed toward the source area 130a in a plane, the other is disposed toward the drain area 130b, and a straight line passing through at least a portion of the first protrusion portion 151b among straight lines parallel to the first direction X may not pass through the second protrusion portion 152b. FIG. 11 illustrates a configuration in which the first protrusion portion 151b is disposed toward the source area 130a, and the second protrusion portion 152b is disposed toward the drain area 130b. However, embodiments of the present di are not limited thereto, and the first protrusion portion 151b may be disposed toward the drain area 130b, and the second protrusion portion 152b may be disposed toward the source area 130a.

In the case of the thin film transistor 900 according to FIG. 11, the length of the channel area 130n may be secured by the protrusion portion 150b and the active hole 135, and conductorization penetration may hardly occur or may be very small. As a result, the thin film transistor 900 may be driven even by the short channel having the length of the short channel area 130n, and a short channel may be implemented.

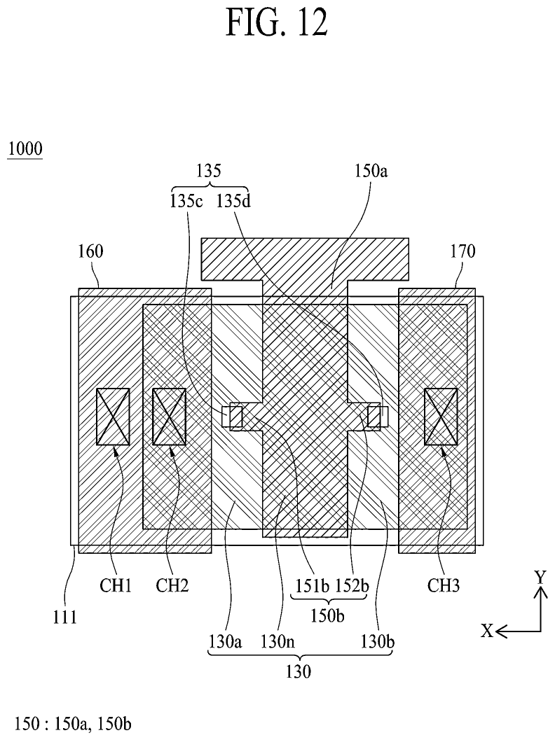

FIG. 12 is a plan view of a thin film transistor 1000 according to another embodiment of the present disclosure.

Compared to FIG. 8, in FIG. 12, one of the first protrusion portion 151b and the second protrusion portion 152b is disposed toward the source area 130a in a plane, the other is disposed toward the drain area 130b, and a straight line passing through at least a portion of the first protrusion portion 151b among straight lines parallel to the first direction X may pass through the second protrusion portion 152b. FIG. 12 shows a configuration in which the first protrusion portion 151b is disposed toward the source area 130a and the second protrusion portion 152b is disposed toward the drain area 130b. However, embodiments of the present disclosure are not limited thereto, and the first protrusion portion 151b may be disposed toward the drain area 130b and the second protrusion portion 152b may be disposed toward the source area 130a.

In the case of the thin film transistor 1000 according to FIG. 12, the length of the channel area 130n may be secured by the protrusion portion 150b and the active hole 135, and conductorization penetration may hardly occur or may be very small. As a result, the thin film transistor 1000 may be driven even by the short channel having the length of the short channel area 130n, and a short channel may be implemented.

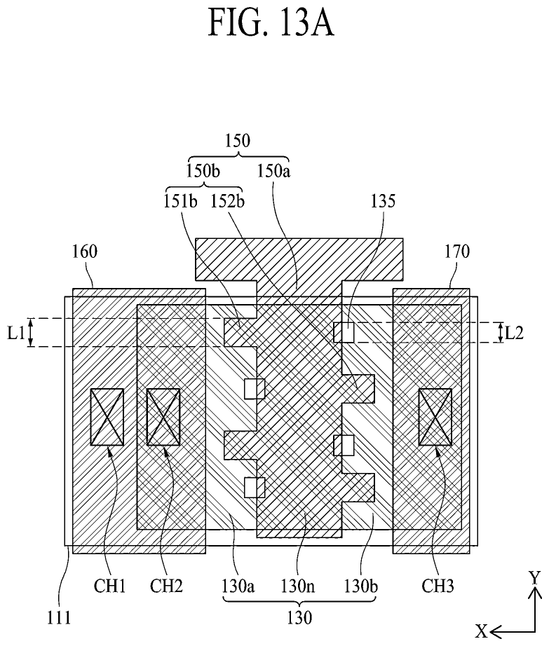

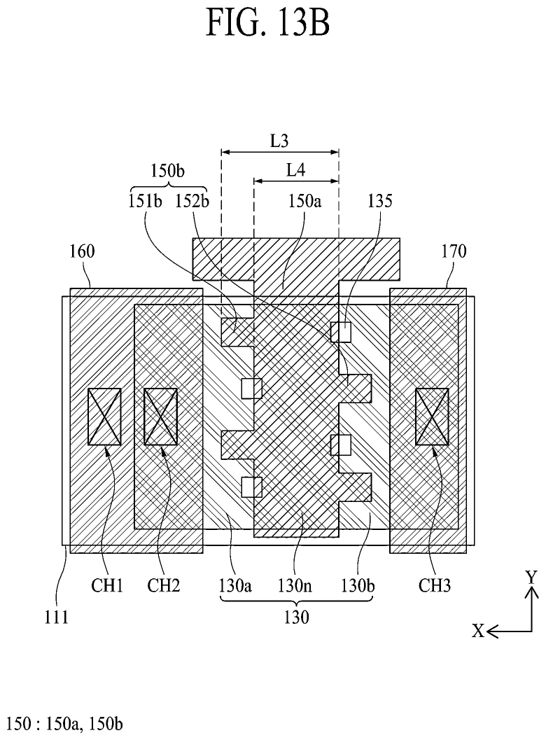

FIG. 13A is a plan view of a thin film transistor 1000 according to another embodiment of the present disclosure. FIG. 13B is a plan view of a thin film transistor 1000 according to another embodiment of the present disclosure.

According to an embodiment of the present disclosure, when a length of an area or line in which an arbitrary straight line parallel to the second direction Y overlaps with the protrusion portion 150b is referred to as L1, and a length of an area or line in which an arbitrary straight line parallel to the second direction Y overlaps with the active hole 135 is referred to as L2, L1 may be greater than or equal to L2.

In FIG. 13A, when lengths of the protrusion portion 150b and the active hole 135 are considered thicknesses based on the second direction Y, the thickness of the protrusion portion 150b may be greater than or equal to the thickness of the active hole 135. Accordingly, the driving stability of the thin film transistor may be secured even by a short channel having the length of the short channel area 130n.

On the other hand, when the thickness of the protrusion portion 150b is smaller than the thickness of the active hole 135, even if a short channel having a length of the short channel area 130n is secured by the protrusion portion 150b and the active hole 135, it may be difficult to secure driving stability of the thin film transistor.

According to an embodiment of the present disclosure, when the length of an area or line in which a straight line passing through the protrusion portion 150b overlaps the gate electrode 150 among any straight lines parallel to the first direction X is L3, and the length of an area or line in which a straight line not passing through the protrusion portion 150b overlaps the gate electrode 150 among any straight lines parallel to the first direction X is L4, L3 may be greater than L4.

In FIG. 13B, when the length of the gate electrode 150 is defined as a width based on the first direction X, the width of the gate electrode 150 passing through the protrusion portion 150b based on the first direction X may be greater than the width of the gate electrode 150 which does not pass through the protrusion portion 150b based on the first direction X. Accordingly, the length of the channel area 130n may be secured, and conductorization penetration may hardly occur or may be very small. As a result, the thin film transistor may be driven even by the short channel having the length of the short channel area 130n, and a short channel may be implemented.

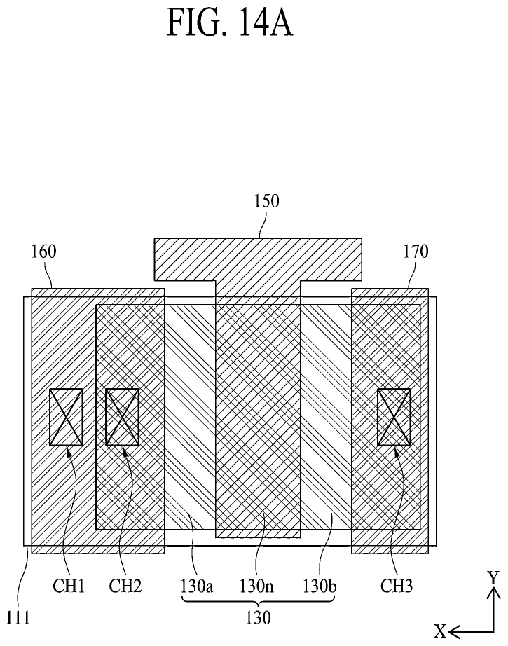

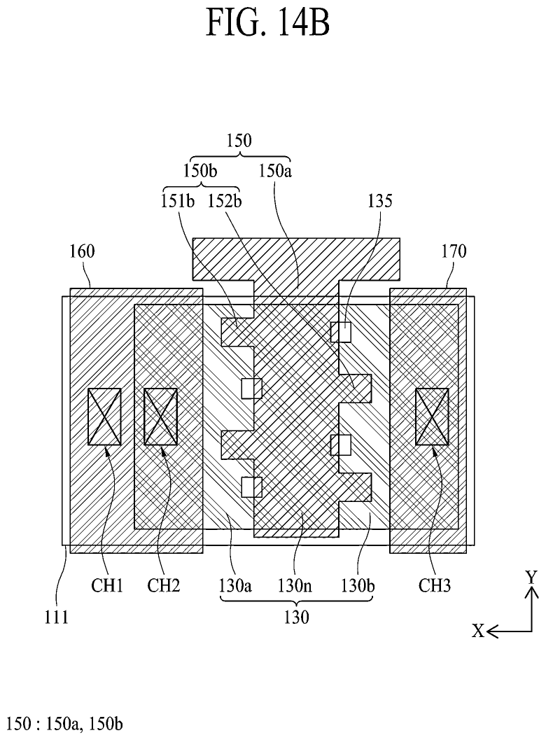

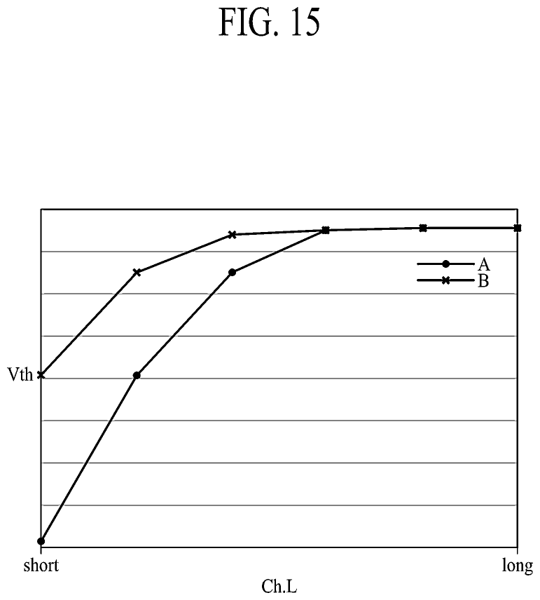

FIG. 14A is a plan view of a thin film transistor according to a comparative example. FIG. 14B is a plan view of a thin film transistor according to another embodiment of the present disclosure. FIG. 15 is a graph showing a measurement of a threshold voltage Vth of a thin film transistor according to embodiments and comparative examples.

In FIG. 15, graph A represents a threshold voltage Vth measurement result of a thin film transistor according to an embodiment, and graph B represents a threshold voltage Vth measurement result of a thin film transistor according to a comparative example.

In FIG. 15, a horizontal axis denotes a length of the channel area 130n, and a vertical axis denotes a threshold voltage (Vth) of the thin film transistor.

As shown in FIG. 14A, the thin film transistor according to the comparative example does not include the active hole 135 and the protrusion portion 150b. On the other hand, as shown in FIG. 14B, the thin film transistor according to an embodiment may include an active hole 135 and a protrusion portion 150b. The thin film transistor according to an embodiment may be any one of the thin film transistors 100, 200, 300, 400, 500, 600, 700, 800, 900, and 1000 of FIG. 1 and FIG. 4 to FIG. 12.

With reference to FIG. 15, in the case of an embodiment A including an active hole 135 and a protrusion portion 150b, the length of the channel area 130n may be secured, and conductorizaton penetration may hardly occur or may be very small. As a result, it may be confirmed that the movement of the threshold voltage (Vth) of the thin film transistor in the negative (−) direction is suppressed even by the short channel having the length of the short channel area 130n.

On the other hand, in the case of the comparative example B that does not include the active hole 135 and the protrusion portion 150b, conductorization of the source area 130a and the drain area 130b may be performed, and thus conductorization diffusion toward the channel area 130n may be significantly performed. As a result, it may be confirmed that the threshold voltage Vth of the thin film transistor moves in the negative (−) direction.

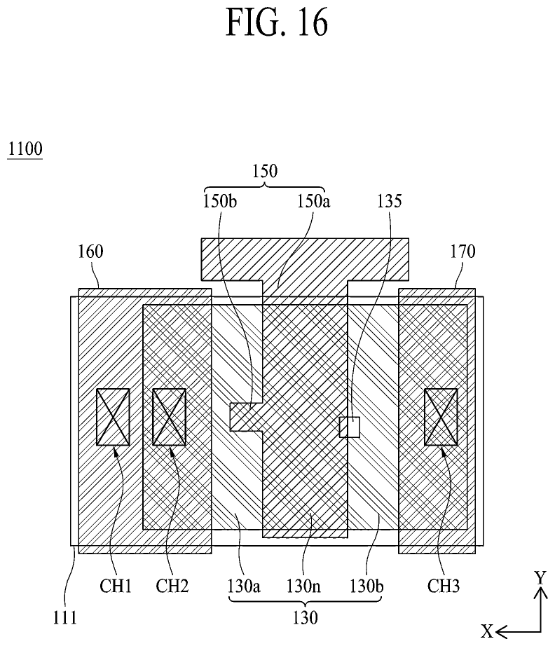

FIG. 16 is a plan view of a thin film transistor 1100 according to another embodiment of the present disclosure.

In FIG. 16, a part of a straight line passing through at least a part of the active hole 135 among straight lines parallel to the first direction X may pass through the protrusion portion 150b, and the other part may not pass through the protrusion portion 150b. Further, a part of the active hole 135 may overlap the protrusion portion 150b with respect to the first direction, and another part of the active hole 135 may not overlap the protrusion portion 150b. Further, the active hole 135 may be disposed to be spaced apart from the protrusion portion 150b with respect to the first direction X in a plane. Even when there are a plurality of protrusion portions 150b and active holes 135, a part of the active holes 135 may be disposed to be spaced apart from the protrusion portion 150b with respect to the first direction X.

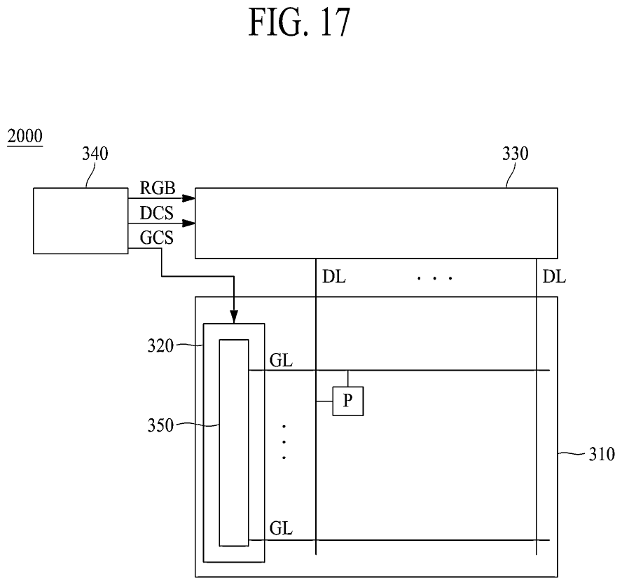

FIG. 17 is a schematic diagram illustrating a display apparatus 2000 according to further still another embodiment of the present disclosure.

As shown in FIG. 17, the display apparatus 2000 according to further still another embodiment of the present disclosure may include a display panel 310, a gate driver 320, a data driver 330 and a controller 340. The display panel 310 includes gate lines GL and data lines DL, and pixels P are disposed in intersection areas of the gate lines GL and the data lines DL. An image is displayed by driving of the pixels P. The gate lines GL, the data lines DL and the pixels P may be disposed on the base substrate 110.

The controller 340 controls the gate driver 320 and the data driver 330. The controller 340 outputs a gate control signal GCS for controlling the gate driver 320 and a data control signal DCS for controlling the data driver 330 by using a signal supplied from an external system not shown. Also, the controller 340 samples input image data input from the external system, realigns the sampled data and supplies the realigned digital image data RGB to the data driver 330.

The gate control signal GCS includes a gate start pulse GSP, a gate shift clock GSC, a gate output enable signal GOE, a start signal Vst and a gate clock GCLK. Also, control signals for controlling a shift register may be included in the gate control signal GCS.

The data control signal DCS includes a source start pulse SSP, a source shift clock signal SSC, a source output enable signal SOE and a polarity control signal POL.

The data driver 330 supplies a data voltage to the data lines DL of the display panel 310. For example, the data driver 330 may convert the image data RGB input from the controller 340 into an analog data voltage and supplies the data voltage to the data lines DL.

According to one embodiment of the present disclosure, the gate driver 320 may be packaged on the display panel 310. In this way, a structure in which the gate driver 320 is directly packaged on the display panel 310 will be referred to as a Gate In Panel (GIP) structure. For example, in the Gate In Panel (GIP) structure, the gate driver 320 may be disposed on the base substrate 110.

The display apparatus 2000 according to one embodiment of the present disclosure may include the above-described thin film transistors 100, 200, 300, 400, 500, 600, 700, 800, 900, 1000, and 1100. According to one embodiment of the present disclosure, the gate driver 320 may include the above-described thin film transistors 100, 200, 300, 400, 500, 600, 700, 800, 900, 1000, and 1100.

The gate driver 320 may include a shift register 350. The shift register 350 sequentially supplies gate pulses to the gate lines GL for one frame by using the start signal and the gate clock, which are transmitted from the controller 340. In this case, one frame means a time period at which one image is output through the display panel 310. The gate pulse has a turn-on voltage capable of turning on a switching device (thin film transistor) disposed in the pixel P.

Also, the shift register 350 supplies a gate-off signal capable of turning off the switching device, to the gate line GL for the other period of one frame, at which the gate pulse is not supplied. Hereinafter, the gate pulse and the gate-off signal will be collectively referred to as a scan signal SS or Scan. The shift register 350 may include the above-described thin film transistors 100, 200, 300, 400, 500, 600, 700, 800, 900, 1000, and 1100.

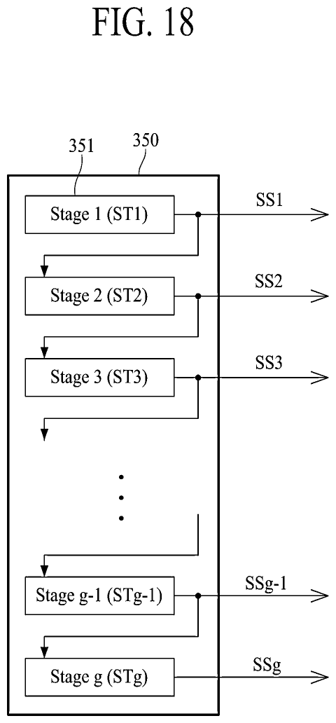

FIG. 18 is a schematic diagram illustrating a shift register 350.

In FIG. 18, the shift register 350 may include g number of stages 351 (ST1 to STg). The shift register 350 transmits one scan signal SS to pixels P connected to one gate line GL through one gate line GL. Each of the stages 351 may be connected to one gate line GL. When g number of gate lines GL are formed in the display panel 110, the shift register 350 may include g number of stages 351 (ST1 to STg), and may generate g number of scan signals SS1 to SSg.

In general, each stage 351 outputs the gate pulse GP once during one frame, and the gate pulses GP are sequentially output from each stage 351.

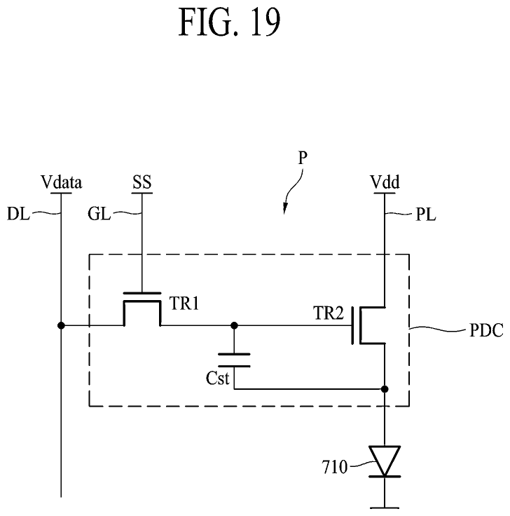

FIG. 19 is a circuit view illustrating any one pixel P of FIG. 17. The circuit view of FIG. 19 is an equivalent circuit view for the pixel P of the display apparatus 2000 that includes an organic light emitting diode (OLED) as a display element 710.

In FIG. 19, the pixel P includes a display element 710 and a pixel driving circuit PDC for driving the display element 710. For example, the display apparatus 2000 according to one embodiment of the present disclosure may include a pixel driving circuit PDC on the base substrate 110.

The pixel driving circuit PDC of FIG. 19 includes a first thin film transistor TR1 that is a switching transistor and a second thin film transistor TR2 that is a driving transistor. The display apparatus 2000 according to another embodiment of the present disclosure may include at least one of the above-described thin film transistors 100, 200, 300, 400, 500, 600, 700, 800, 900, 1000 and 1100.

The first thin film transistor TR1 is connected to the gate line GL and the data line DL, and is turned on or off by the scan signal SS supplied through the gate line GL.

The data line DL provides a data voltage Vdata to the pixel driving circuit PDC, and the first thin film transistor TR1 controls applying of the data voltage Vdata.

The driving power line PL provides a driving voltage Vdd to the display element 710, and the first thin film transistor TR1 controls the driving voltage Vdd. The driving voltage Vdd is a pixel driving voltage for driving the organic light emitting diode (OLED) that is the display element 710.

When the first thin film transistor TR1 is turned on by the scan signal SS applied from the gate driver 320 through the gate line GL, the data voltage Vdata supplied through the data line DL is supplied to a gate electrode of the second thin film transistor TR2 connected to the display element 710. The data voltage Vdata is charged in a storage capacitor Cst formed between the gate electrode and a source electrode of the second thin film transistor TR2.

The amount of a current supplied to the organic light emitting diode (OLED), which is the display element 710, through the second thin film transistor TR2 is controlled in accordance with the data voltage Vdata, whereby a gray scale of light output from the display element 710 may be controlled.

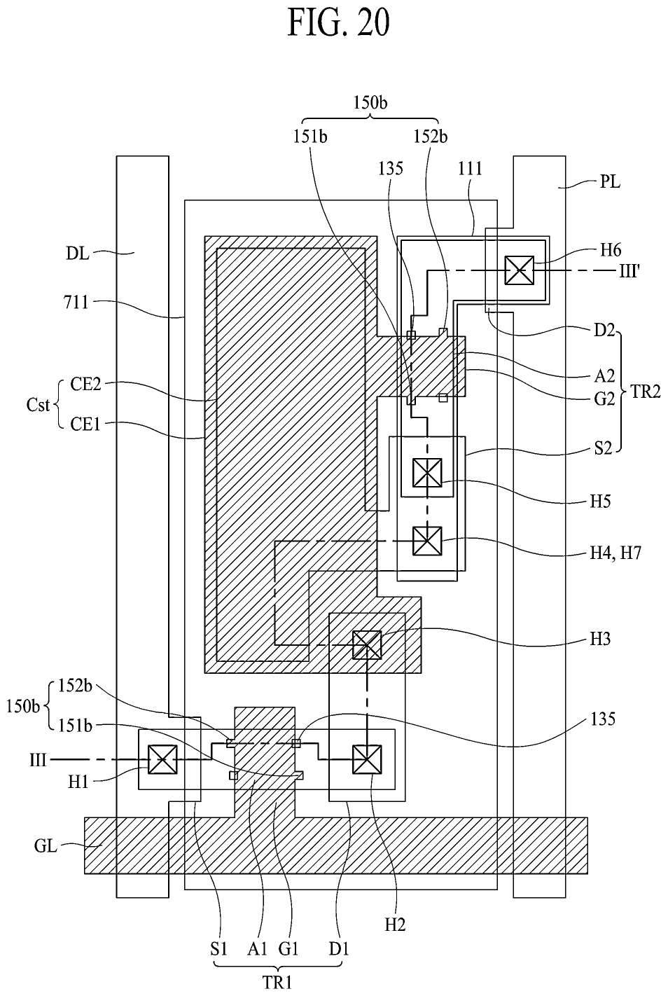

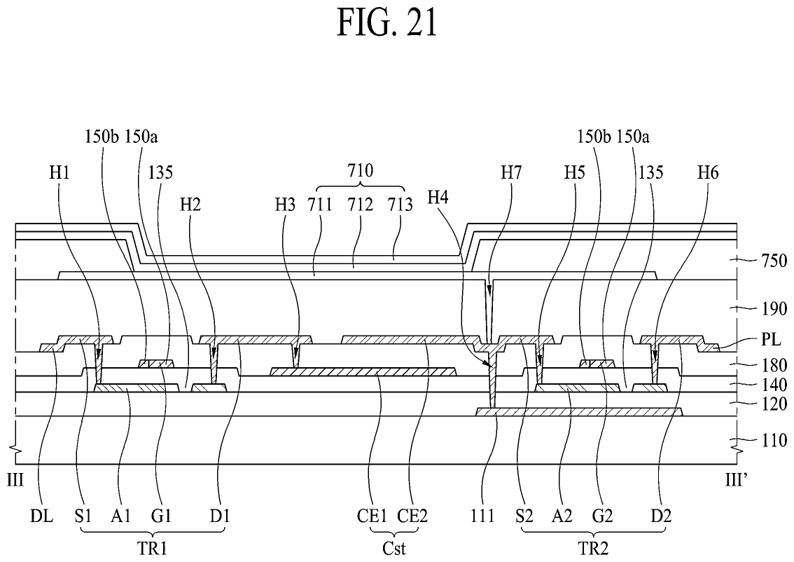

FIG. 20 is a plan view of the pixel of FIG. 19, and FIG. 21 is a cross-sectional view taken along line III-III′ of FIG. 20.

As shown in FIGS. 20 and 21, the first thin film transistor TR1 and the second thin film transistor TR2 are disposed on the base substrate 110. The base substrate 110 may be made of glass or plastic. As the base substrate 110, plastic having flexible characteristics, for example, polyimide (PI), may be used.

The light blocking layer 111 is disposed on the base substrate 110. The light blocking layer 111 may have a light blocking characteristic. The light blocking layer 111 may block light incident from the outside to protect the active layers A1 and A2.

The buffer layer 120 is disposed on the light blocking layer 111. The buffer layer 120 is made of an insulating material and protects the active layers A1 and A2 from moisture or oxygen introduced from the outside.

A first active layer A1 of the first thin film transistor TR1 and a second active layer A2 of the second thin film transistor TR2 are disposed on the buffer layer 120.

The first active layer A1 and the second active layer A2 may include, for example, an oxide semiconductor material. The first active layer A1 and the second active layer A2 may be formed of an oxide semiconductor layer made of an oxide semiconductor material.

In the first thin film transistor TR1, the first active layer A1 may include a channel area, a source area, and a drain area. A channel area of the first active layer A1 overlaps the gate electrode G1. According to another embodiment of the present disclosure, a source area may be referred to as a source electrode S1, and a drain area may be referred to as a drain electrode D1.

In the second thin film transistor TR2, the second active layer A2 may include a channel area, a source area, and a drain area. The channel area of the second active layer A2 overlaps the gate electrode G2. According to another embodiment of the present disclosure, a source area may be referred to as a source electrode S2, and a drain area may be referred to as a drain electrode D2.

In the first thin film transistor TR1, an active hole 135 in which the first active layer A1 is not disposed is disposed in an area in which an edge thereof is defined by the first active layer A1. The active hole 135 may be an area formed by removing the active layers A1 and A2.

At least a portion of the active hole 135 may overlap the gate electrodes G1 and G2. The gate insulating layer 140 is disposed on the active layers A1 and A2. The gate insulating layer 140 covers upper surfaces of the active layers A1 and A2.

The gate electrode G1 of the first thin film transistor TR1 and the gate electrode G2 of the second thin film transistor TR2 are disposed on the gate insulating layer 140. Although not shown in the drawings, a gate line GL may be disposed on the gate insulating layer 140. The gate electrode G1 of the first thin film transistor TR1 may extend from the gate line GL or may be a part of the gate line GL.

In FIGS. 20 and 21, a first capacitor electrode CE1 of the storage capacitor Cst is formed on the gate insulating layer 140. The first capacitor electrode CE1 may be formed by the same material as the gate electrodes G1 and G2 by the same process. An interlayer insulating layer 180 is disposed on the gate electrodes G1 and G2 and the first capacitor electrode CE1.

A data line DL and a driving power line PL are disposed on the interlayer insulating layer 180. Also, the source electrode S1 and the drain electrode D1 of the first thin film transistor TR1 are disposed on the interlayer insulating layer 180, and the source electrode S2 and the drain electrode D2 of the second thin film transistor TR2 are disposed on the interlayer insulating layer 180.

The source electrode S1 of the first thin film transistor TR1 may be integrally formed with the data line DL, and may have a structure extending from the data line DL. The source electrode S1 of the first thin film transistor TR1 may be in contact with the side surface of the active layer A1 of the first thin film transistor TR1 through the first contact hole H1.

A drain electrode D1 of the first thin film transistor TR1 contacts another side surface of the active layer A1 of the first thin film transistor TR1 through a second contact hole H2. Also, a drain electrode D1 of the first thin film transistor TR1 is connected to the first capacitor electrode CE1 through a third contact hole H3. As a result, the first capacitor electrode CE1 may be connected to the first thin film transistor TR1.

The drain electrode D2 of the second thin film transistor TR2 may be integrally formed with the driving power line PL, and may have a structure extending from the driving power line PL. The drain electrode D2 of the second thin film transistor TR2 may be in contact with the side surface of the active layer A2 of the second thin film transistor TR2 through the sixth contact hole H6.

The source electrode S2 of the second thin film transistor TR2 is in contact with the other side surface of the active layer A2 of the second thin film transistor TR2 through the fifth contact hole H5. Also, the source electrode S2 of the second thin film transistor TR2 is connected to the light blocking layer 111 through the fourth contact hole H4. The same voltage as the source electrode S2 of the second thin film transistor TR2 may be applied to the light blocking layer 111 overlapping the second thin film transistor TR2.

The source electrode S2 of the second thin film transistor TR2 may extend onto the interlayer insulating layer 180 to form the second capacitor electrode CE2 of the storage capacitor Cst.

According to an embodiment of the present disclosure, the first capacitor electrode CE1 and the second capacitor electrode CE2 may overlap to form a storage capacitor Cst.

As illustrated in FIGS. 20 and 21, a planarization layer 190 is disposed on the data line DL, the driving power line PL, the source electrodes S1 and S2, the drain electrodes D1 and D2, and the second capacitor electrode CE2. The planarization layer 190 planarizes upper portions of the first thin film transistor TR1 and the second thin film transistor TR2, and protects the first thin film transistor TR1 and the second thin film transistor TR2. The planarization layer 190 serves as a protective layer.

A first electrode 711 of the display element 710 is disposed on the planarization layer 190. The first electrode 711 of the display element 710 is in contact with the second capacitor electrode CE2 through a seventh contact hole H7 formed in the planarization layer 190. As a result, the first electrode 711 of the display element 710 may be connected to the source electrode S2 of the second thin film transistor TR2.

A bank layer 750 is disposed at an edge of the first electrode 711. The bank layer 750 defines a light emitting area of the display element 710.

The organic light emitting layer 712 is disposed on the first electrode 711, and the second electrode 713 is disposed on the organic light emitting layer 712. Accordingly, the display element 710 is completed. The display element 710 shown in FIG. 21 is an organic light emitting diode (OLED). Therefore, the display apparatus 2000 according to an embodiment of the present disclosure is an organic light emitting display apparatus.

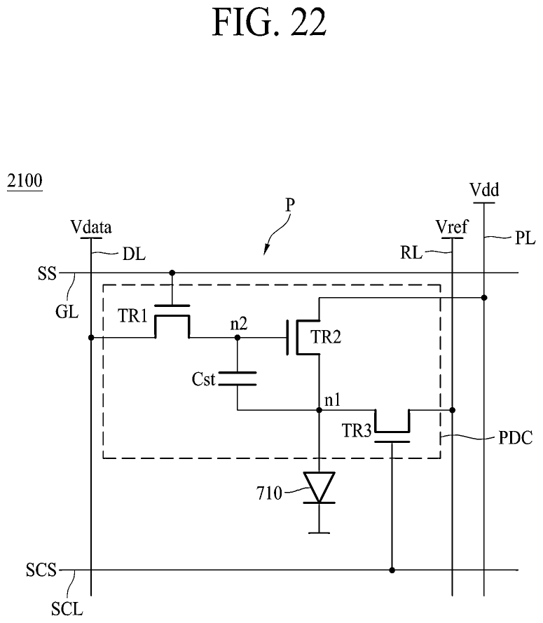

FIG. 22 is a circuit diagram of any one pixel of a display apparatus 2100 according to another embodiment of the present disclosure.

FIG. 22 is an equivalent circuit diagram of a pixel P of an organic light emitting display apparatus. The pixel P of the display apparatus 2100 shown in FIG. 22 includes an organic light emitting diode OLED, which is a display element 710, and a pixel driving circuit PDC for driving the display element 710. The display element 710 is connected to the pixel driving circuit PDC.

Signal lines DL, GL, PL, RL, and SCL for supplying signals to the pixel driving circuit PDC are arranged in the pixel P. The data voltage Vdata is supplied to the data line DL, the scan signal SS is supplied to the gate line GL, the driving voltage Vdd for driving the pixel is supplied to the driving power line PL, the reference voltage Vref is supplied to the reference line RL, and the sensing control signal SCS is supplied to the sensing control line SCL.

The pixel driving circuit PDC includes, for example, the first thin film transistor TR1 (switching transistor) connected to the gate line GL and the data line DL, the second thin film transistor TR2 (driving transistor) that controls the magnitude of the current output to the display element 710 according to the data voltage Vdata transmitted through the first thin film transistor TR1, and the third thin film transistor TR3 (sensing transistor) for sensing the characteristics of the second thin film transistor TR2.

The first thin film transistor TR1 is turned on by the scan signal SS supplied to the gate line GL, and transmits the data voltage Vdata supplied to the data line DL to the gate electrode of the second thin film transistor TR2.

The third thin film transistor TR3 is connected to the first node n1 and the reference line RL between the second thin film transistor TR2 and the display element 710, is turned on or off by the sensing control signal SCS, and detects characteristics of the second thin film transistor TR2, which is a driving transistor during the sensing period.

A second node n2 connected to the gate electrode of the second thin film transistor TR2 is connected to the first thin film transistor TR1. A storage capacitor Cst is formed between the second node n2 and the first node n1.

When the first thin film transistor TR1 is turned on, the data voltage Vdata supplied through the data line DL is supplied to the gate electrode of the second thin film transistor TR2. The data voltage Vdata is charged in the storage capacitor Cst formed between the gate electrode and the source electrode of the second thin film transistor TR2. When the second thin film transistor TR2 is turned on, current is supplied to the display element 710 through the second thin film transistor TR2 by the driving voltage Vdd driving the pixel, and light is output from the display element 710.

The display apparatus 2100 according to another embodiment of the present disclosure may include at least one of the thin film transistors 100, 200, 300, 400, 500, 600, 700, 800, 900, 1000, and 1100.

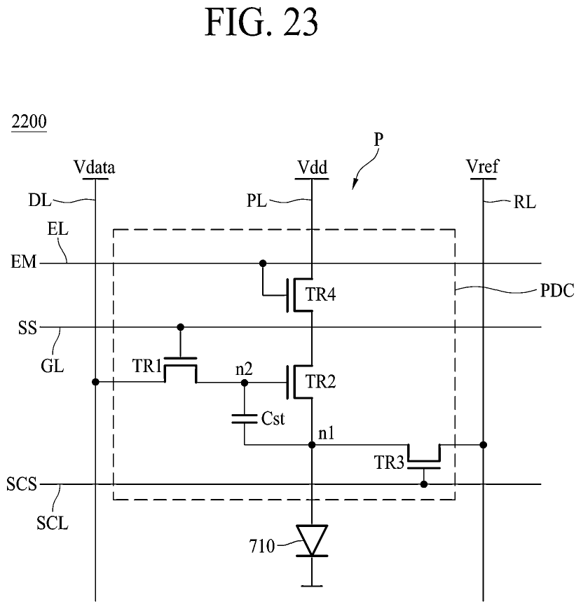

FIG. 23 is a circuit diagram of any one pixel P of a display apparatus 2200 according to another embodiment of the present disclosure.

The pixel P of the display apparatus 2200 shown in FIG. 23 includes an organic light emitting diode OLED, which is a display element 710, and a pixel driving circuit PDC for driving the display element 710. The display element 710 is connected to the pixel driving circuit PDC. The pixel driving circuit PDC includes thin film transistors TR1, TR2, TR3, and TR4. Signal lines DL, EL, GL, PL, SCL, and RL that supply driving signals to the pixel driving circuit PDC are arranged in the pixel P.

Compared with the pixel P of FIG. 22, the pixel P of FIG. 23 further includes an emission control line EL. The emission control signal EM is supplied to the emission control line EL. Also, compared with the pixel driving circuit PDC of FIG. 22, the pixel driving circuit PDC of FIG. 23 further includes a fourth thin film transistor TR4, which is an emission control transistor for controlling a emission time point of the second thin film transistor TR2.

The first thin film transistor TR1 is turned on by the scan signal SS supplied to the gate line GL, and transmits the data voltage Vdata supplied to the data line DL to the gate electrode of the second thin film transistor TR2. A storage capacitor Cst is positioned between the gate electrode of the second thin film transistor TR2 and the display element 710.

The third thin film transistor TR3 is connected to the reference line RL, is turned on or off by the sensing control signal SCS, and detects characteristics of the second thin film transistor TR2, which is a driving transistor, during the sensing period. The fourth thin film transistor TR4 transfers the driving voltage Vdd to the second thin film transistor TR2 or blocks the driving voltage Vdd according to the emission control signal EM. When the fourth thin film transistor TR4 is turned on, a current is supplied to the second thin film transistor TR2 to output light from the display element 710.

The pixel driving circuit PDC according to another example configuration of the present disclosure may be formed in various structures other than the structure described above. The pixel driving circuit PDC may include, for example, five or more thin film transistors.

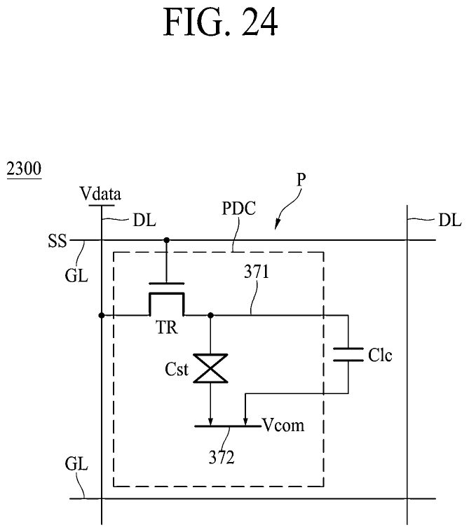

FIG. 24 is a circuit diagram of any one pixel of a display apparatus 2300 according to another embodiment of the present disclosure.

The pixel P of the display apparatus 2300 illustrated in FIG. 24 includes a pixel driving circuit PDC and a liquid crystal capacitor Clc connected to the pixel driving circuit PDC. The liquid crystal capacitor Clc corresponds to a display device. The display apparatus 2300 of FIG. 24 is a liquid crystal display device.

The pixel driving circuit PDC includes a thin film transistor TR connected to the gate line GL and the data line DL, a pixel electrode 371 connected to the thin film transistor TR, a common electrode 372 opposite to the pixel electrode 371, and a storage capacitor Cst connected between the thin film transistor TR and the common electrode 372. The liquid crystal capacitor Clc is connected in parallel with the storage capacitor Cst between the thin film transistor TR and the common electrode 372.

The liquid crystal capacitor Clc is charged with a difference voltage between the data signal supplied to the pixel electrode through the thin film transistor TR and the common voltage Vcom supplied to the common electrode 372, and drives the liquid crystal according to the charged voltage to control the amount of light transmission. The storage capacitor Cst stably maintains the voltage charged in the liquid crystal capacitor Clc.

The display apparatus 2300 according to another embodiment of the present disclosure may include at least one of the above-described thin film transistors 100, 200, 300, 400, 500, 600, 700, 800, 900, 1000, and 1100.

According to the present disclosure, the following advantageous effects may be obtained.

The thin film transistor according to an embodiment of the present disclosure may prevent or suppress the threshold voltage Vth from being shifted in the negative (−) direction even if it has a short channel, including a protrusion portion and an active hole.

A thin film transistor according to an embodiment of the present disclosure may control a conductorizaton penetration depth even if it has a short channel, including a protrusion portion and an active hole.

The thin film transistor according to a configuration of the present disclosure may have excellent reliability, including a protrusion portion and an active hole.

In addition to the above-mentioned effects, other features and advantages of the present disclosure will be described below or clearly understood by those of ordinary skill in the art to which the present disclosure belongs from such technology and description.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A thin film transistor, comprising:
an active layer; and
a gate electrode spaced apart from the active layer and partially overlapping the active layer,
wherein the active layer includes:
a channel area partially overlapping the gate electrode in a plan view;
a source area connected to one side of the channel area in the plan view; and
a drain area connected to the other side of the channel area in the plan view,
wherein the active layer defines an active hole in which the active layer absent, at least a part of the active hole overlaps the gate electrode in the plan view, and at least another part of the active hole extends beyond an edge of the gate electrode in the plan view, and
wherein the gate electrode includes a body portion and a protrusion portion protruding in a first direction, the first direction being a direction parallel to the shortest line connecting the source area and the drain area.

2. The thin film transistor of claim 1, wherein a straight line passing through at least a portion of the active hole among straight lines parallel to the first direction passes under the protrusion portion in the plan view.

3. The thin film transistor of claim 1, wherein the protrusion portion does not overlap the active hole in the plan view.

4. The thin film transistor of claim 1, wherein the protrusion portion overlaps at least a portion of the active hole in the plan view.

5. The thin film transistor of claim 1, wherein the protrusion portion includes a first protrusion portion and a second protrusion portion spaced apart from each other, and
wherein the active hole includes a first active hole and a second active hole spaced apart from each other.

6. The thin film transistor of claim 5, wherein, in the plan view, the first active hole and the second active hole do not overlap either of the first protrusion portion or the second protrusion portion.

7. The thin film transistor of claim 6, wherein, in the plan view, the first protrusion portion and the second protrusion portion protrude in the first direction from a side of the body portion toward the source area,
wherein, in the plan view, the first active hole and the second active hole are disposed in the first direction on a side the gate electrode toward the drain area, and
wherein, in the plan view, a straight line in the first direction passes through at least a portion of the first active hole and under the protrusion portion.

8. The thin film transistor of claim 6, wherein, in the plan view, the first protrusion portion and the second protrusion portion protrude in the first direction from a side of the body portion toward the drain area,
wherein, in the plan view, the first active hole and the second active hole are disposed in the first direction on a side of the gate electrode toward the source area, and
wherein, in the plan view, a straight line in the first direction passes through at least a portion of the active hole and under the protrusion portion.

9. The thin film transistor of claim 6, wherein, in the plan view, one of the first protrusion portion and the second protrusion portion protrudes in the first direction from a side of the body portion toward the source area, the other one of the first protrusion portion and the second protrusion portion protrudes in the first direction from another side of the body portion toward the drain area,
wherein, in the plan view, one of the first active hole and the second active hole is disposed in the first direction on a side of the gate electrode toward the source area in the first direction in a plane, the other one of the first active hole and the second active hole is disposed in the first direction on another side of the gate electrode toward the drain area, and
wherein, in the plan view, a straight line in the first direction passes through at least a portion of one of the first active hole and the second active hole and through at least one of the first protrusion portion and the second protrusion portion.

10. The thin film transistor of claim 9, wherein, in the plan view, a straight line in a first direction passing through at least a portion of the first protrusion portion does not pass over the second protrusion portion.

11. The thin film transistor of claim 1, wherein the protrusion portion includes a first protrusion portion and a second protrusion portion spaced apart from each other,
wherein the active hole includes a third active hole and a fourth active hole spaced apart from each other,
wherein the third active hole overlaps the first protrusion portion, and
wherein the fourth active hole overlaps the second protrusion portion.

12. The thin film transistor of claim 11, wherein the active hole further includes a first active hole and a second active hole spaced apart from each other,
wherein the first active hole and the second active hole do not overlap any of the first protrusion portion and the second protrusion portion,
wherein at least a portion of the first protrusion portion, at least a portion of the first active hole, and at least a portion of the third active hole are disposed on a first straight line extending along the first direction in the plan view, and
wherein at least a portion of the second protrusion portion, at least a portion of the second active hole, and at least a portion of the fourth active hole are disposed on a second straight line extending along the first direction in the plan view.

13. The thin film transistor of claim 12, wherein, in the plan view, the first protrusion portion and the second protrusion portion are disposed on a side of the body portion toward the source area in the first direction, and
wherein, in the plan view, the first active hole and the second active hole are disposed on another side of the body portion toward the drain area in the first direction.

14. The thin film transistor of claim 12, wherein, in the plan view, the first protrusion portion and the second protrusion portion are disposed on a side of the body portion toward the drain area in the first direction, and
wherein, in the plan view, the first active hole and the second active hole are disposed on another side of the body portion toward the source area in the first direction.

15. The thin film transistor of claim 12, wherein, in the plan view, one of the first protrusion portion and the second protrusion portion is disposed on a side of the body portion toward the source area, and the other one of the first protrusion portion and the second protrusion portion is disposed on another side of the body portion toward the drain area, and
wherein a straight line in the first direction passing through at least a portion of the first protrusion portion does not pass through the second protrusion portion.

16. The thin film transistor of claim 11, wherein, in the plan view, one of the first protrusion portion and the second protrusion portion is disposed on a side of the body portion toward the source area, and the other one of the first protrusion portion and the second protrusion portion is disposed on another side of the body portion toward the drain area, and
wherein a straight line in the first direction passing through at least a portion of the first protrusion portion passes through the second protrusion portion.

17. The thin film transistor of claim 1, wherein a second direction is a direction perpendicular to the first direction, and
wherein, a width of the protrusion portion in the second direction is greater than or equal to a width of the active hole in the second direction.

18. The thin film transistor of claim 1, wherein a length in the first direction of the gate electrode at a portion including the body portion and the protrusion portion is greater than a length in the first direction of the gate electrode at a portion including the body portion where the protrusion is absent.

19. The thin film transistor of claim 1, wherein the protrusion portion protrudes to overlap a portion of one of the source area and the drain area of the active layer.

20. The thin film transistor of claim 1, wherein, in the plan view, a first straight line in the first direction passing through at least a portion of the active hole passes under the protrusion portion, and a second straight line in the first direction passing through at least a portion of the active hole does not pass under the protrusion portion.

21. The thin film transistor of claim 1, wherein an area of a region occupied by the protrusion portion is larger than an area of a region occupied by the active hole in the plan view.

22. A display apparatus comprising the thin film transistor of claim 1.
